(19) United States
(12) Patent Application Publication
(10) Pub. No.: US 2025/0257262 A1
(43) Pub. Date: Aug. 14, 2025

(54) FLUORIDE PHOSPHOR, METHOD FOR MANUFACTURING FLUORIDE PHOSPHOR, AND LIGHT-EMITTING DEVICE

(71) Applicant: NICHIA CORPORATION, Anan-shi (JP)

(72) Inventor: Tomokazu YOSHIDA, Anan-shi (JP)

(73) Assignee: NICHIA CORPORATION, Anan-shi (JP)

(21) Appl. No.: 19/053,246

(22) Filed: Feb. 13, 2025

(30) Foreign Application Priority Data
Feb. 14, 2024 (JP) 2024-020378

(51) Int. Cl. C09K 11/61; C01G 45/22; H10H 20/851

(52) U.S. Cl. CPC C09K 11/615; C01G 45/22; H10H 20/8512; C01P 2002/72; C01P 2004/03; C01P 2006/60

(57) ABSTRACT

Provided is a fluoride phosphor including a fluoride particle and a fluorine compound containing zirconium and disposed on at least a portion of the surface of the fluoride particle. The fluoride particle has a composition including an element M including at least one selected from the group consisting of Group 4 elements, Group 13 elements, and Group 14 elements; at least one selected from the group consisting of an alkali metal and an ammonium ion; manganese; and fluorine atoms. In the composition, when the total number of moles of the alkali metal and the ammonium ion is 2, the number of moles of the manganese is greater than 0 and less than 0.2, the total number of moles of the element M is greater than 0.8 and less than 1, and the number of moles of the fluorine atoms is greater than 5 and less than 7.

### CROSS-REFERENCE TO RELATED APPLICATION

This application claims priority to Japanese Patent Application No. 2024-020378, filed on Feb. 14, 2024, the disclosure of which is hereby incorporated by reference in its entirety.

### TECHNICAL FIELD

The present disclosure relates to a fluoride phosphor, a method for manufacturing the fluoride phosphor, and a light-emitting device.

### BACKGROUND

Light-emitting devices in which a light-emitting element and a phosphor are combined are used in a wide range of fields, such as in lighting, vehicle-mounted lighting, displays, and liquid crystal backlights. For example, a phosphor used in a light-emitting device for a liquid crystal backlight application is needed to have high color purity, that is, the full width at half maximum of the emission peak is needed to be narrow. A fluoride phosphor in which manganese is added is known as a red-light emitting phosphor having a narrow full width at half maximum of the emission peak.

For example, Japanese Patent Publication No. 2019-525974 T indicates that a manganese-doped red phosphor is coated with aluminum oxide or the like in order to reduce the issue of instability due to deterioration of the manganese-doped red phosphor, and further describes a light-emitting device provided with a fluorescent member containing the coated manganese-doped red phosphor.

### SUMMARY

In a light-emitting device provided with a wavelength conversion member containing a fluoride phosphor that contains manganese, the reliability of the light-emitting device may decrease depending on the environment in which the light-emitting device is used. As such, an object of one aspect of the present disclosure is to provide a fluoride phosphor that can further improve the reliability of a light-emitting device, and a method for manufacturing the fluoride phosphor.

A first aspect is a fluoride phosphor containing a fluoride particle; and a fluorine compound containing zirconium and disposed on at least a portion of a surface of the fluoride particle. The fluoride particle has a composition including an element M including at least one selected from the group consisting of Group 4 elements, Group 13 elements, and Group 14 elements; at least one selected from the group consisting of an alkali metal and an ammonium ion; manganese; and fluorine atoms, wherein, when the total number of moles of the alkali metal and the ammonium ion is 2, the number of moles of the manganese is greater than 0 and less than 0.2, the total number of moles of the element M is greater than 0.8 and less than 1, and the number of moles of the fluorine atoms is greater than 5 and less than 7.

A second aspect is a method for manufacturing a fluoride phosphor, the method including providing a fluoride particle having a composition including an element M including at least one selected from the group consisting of Group 4 elements, Group 13 elements, and Group 14 elements; at least one selected from the group consisting of an alkali metal and an ammonium ion; manganese; and fluorine atoms, wherein, when the total number of moles of the alkali metal and the ammonium ion is 2, the number of moles of the manganese is greater than 0 and less than 0.2, the total number of moles of the element M is greater than 0.8 and less than 1, and the number of moles of the fluorine atoms is greater than 5 and less than 7; and bringing the fluoride particle into contact with a treatment solution containing a complex ion containing zirconium and a fluoride ion, and thereby disposing a zirconium-containing fluorine compound on at least a portion of a surface of the fluoride particle.

A third aspect is a light-emitting device including the fluoride phosphor of the first aspect, and a light source having an emission peak wavelength in a range of 380 nm to 485 nm.

According to one aspect of the present disclosure, a fluoride phosphor that can further improve the reliability of a light-emitting device, and a method for manufacturing the fluoride phosphor can be provided.

### BRIEF DESCRIPTION OF DRAWINGS

FIG. 1 is a schematic cross-sectional view illustrating one example of a light-emitting device that uses a fluoride phosphor.

FIG. 2 is an example of a scanning electron microscope image of a fluoride phosphor according to Example 1.

FIG. 3 is an example of a scanning electron microscope image of a fluoride phosphor according to Example 3.

FIG. 4 is an example of X-ray diffraction spectra of fluoride phosphors.

### DETAILED DESCRIPTIONS

In the present specification, the word “step” herein includes not only an independent step, but also a step that cannot be clearly distinguished from another step if the anticipated purpose of the step is achieved. When a plurality of substances applicable to a single component in a composition are present, the content of the single component in the composition means the total amount of the plurality of substances present in the composition, unless otherwise specified. Furthermore, with respect to upper and lower limits of numerical ranges described herein, the numerical values exemplified as the numerical ranges can be freely selected and combined. In the present specification, a plurality of elements separated by commas (,) in a formula representing the composition of the phosphor or light-emitting material means that at least one element among the plurality of elements is contained in the composition. In a formula representing the composition of the phosphor, any element preceding the colon (:) represents a host crystal, and any element following the colon (:) represents an activating element. Note that herein, the relationship between a color name and chromaticity coordinates, the relationship between a wavelength range of light and a color name of monochromatic light are in accordance with JIS Z8110. The full width at half maximum of a phosphor means a wavelength width (full width at half maximum: FWHM) in an emission spectrum at which the emission intensity becomes 50% of the maximum emission intensity in the emission spectrum of the phosphor. Embodiments of the present disclosure are described below in detail. The embodiments presented below exemplify a fluoride phosphor, a method for manufacturing the fluoride phosphor, and a light-emitting device, which all embody the technical concept of the present disclosure, but the present disclosure is not limited to the fluoride phosphor, the method for manufacturing the fluoride phosphor, or the light-emitting device presented below.

### Fluoride Phosphor

The fluoride phosphor may contain fluoride particles and a fluorine compound containing zirconium and disposed on at least a portion of the surface of each fluoride particle. The composition of the fluoride particles may contain an element M including at least one element selected from the group consisting of Group 4 elements, Group 13 elements, and Group 14 elements; one selected from the group consisting of an alkali metal and an ammonium ion; manganese; and fluorine atoms. In the composition of the fluoride particles, when the total number of moles of the alkali metal and the ammonium ion is 2, the number of moles of the manganese may be greater than 0 and less than 0.2, the total number of moles of the element M may be greater than 0.8 and less than 1, and the number of moles of fluorine atoms may be greater than 5 and less than 7.

A light-emitting device including a fluoride phosphor in which a fluorine compound containing zirconium is disposed on the surfaces of fluoride particles that are a fluorescent substance can exhibit good reliability by reducing or preventing a decrease in luminous flux, a color change, or the like, even in a usage environment such as a high-temperature environment or a high-temperature and high-humidity environment, for example. The reason for this is considered to be as follows, for example. The good reliability can be considered to be due to a suppression of the deterioration of the fluoride phosphor in a high-temperature environment or a high-temperature and high-humidity environment by disposing, on the surfaces of the fluoride particles, a zirconium-containing fluorine compound of a composition that differs from that of the fluoride particles and does not contain manganese ions, which can cause a decrease in luminous flux or a color change.

The fluoride particles contained in the fluoride phosphor may contain at least a fluorescent substance that is activated by manganese (Mn), or may consist of only a fluorescent substance that is activated by Mn. The composition of the fluoride particles is such that when the total number of moles of the alkali metal and ammonium ion is 2, the number of moles of Mn may be greater than 0 and less than 0.2, and is preferably in a range of 0.01 to 0.12. The composition of the fluoride particles is also such that when the total number of moles of the alkali metal and the ammonium ion is 2, the number of moles of the element M may be greater than 0.8 and less than 1, and is preferably in a range of 0.88 to 0.99. The composition of the fluoride particles is also such that when the number of moles of the alkali metal is 2, the number of moles of F may be greater than 5 and less than 7, and is preferably in a range of 5.9 to 6.1. The composition of the fluoride particles can be measured, for example, by inductively coupled plasma (ICP) emission spectroscopy.

The alkali metal in the composition of the fluoride particles may include at least one selected from the group consisting of lithium (Li), sodium (Na), potassium (K), rubidium (Rb), and cesium (Cs). The alkali metal may include at least potassium (K), and at least one selected from the group consisting of lithium (Li), sodium (Na), rubidium (Rb), and cesium (Cs). A ratio of the number of moles of K to the total number of moles of the alkali metal and the ammonium ion in the composition may be, for example, 0.90 or greater, and is preferably 0.95 or greater, or 0.97 or greater. The upper limit of the ratio of the number of moles of K may be, for example, 1 or less, or 0.995 or less. The composition of the fluoride particles may contain an ammonium ion (NH₄⁺) instead of the alkali metal. When the composition contains an ammonium ion, a ratio of the number of moles of the ammonium ion to the total number of moles of the alkali metal and the ammonium ion in the composition may be, for example, 0.10 or less, and is preferably 0.05 or less, or 0.03 or less. The lower limit of the ratio of the number of moles of the ammonium ion may be, for example, greater than 0, and may be preferably 0.005 or greater.

The element M in the composition of the fluoride particles includes at least one element selected from the group consisting of Group 4 elements, Group 13 elements, and Group 14 elements. Examples of Group 4 elements include titanium (Ti), zirconium (Zr), and hafnium (Hf), and at least one selected from the group consisting of these elements may be included. Examples of Group 13 elements include boron (B), aluminum (Al), gallium (Ga), indium (In), and thallium (Tl), and at least one selected from the group consisting of these elements may be included. Examples of Group 14 elements include carbon (C), silicon (Si), germanium (Ge), and tin (Sn), and at least one selected from the group consisting of these elements may be included. The element M may include at least one element of at least the Group 14 elements, may preferably include at least one of at least Si and Ge, and may more preferably include at least Si. In addition, the element M may include at least, at least one element of the Group 13 elements and at least one element of the Group 14 elements, preferably includes at least Al and at least one of Si or Ge, and more preferably includes at least Al and Si.

In the fluoride particle composition, the total number of moles of the elements M and Mn per a total number of 2 moles of the alkali metal and the ammonium ion may be in a range from 0.9 to 1.1, preferably from 0.95 to 1.05, or from 0.97 to 1.03.

The composition of the fluoride particles may be a composition represented by Formula (1) below.

A_{c}[M_{1-b}Mn_{b}F_{d}] (1)

In Formula (1), A may include at least one selected from the group consisting of Li, Na, K, Rb, Cs, and NH₄⁺. M includes at least Si, and may further include at least one element selected from the group consisting of Group 4 elements, Group 13 elements, and Group 14 elements. Mn may be a tetravalent Mn ion. Moreover, b may satisfy 0<b<0.2, c is the absolute value of the charge of the [M_{1-b}Mn_{b}F_{d}] ion, and d may satisfy 5<d<7.

A in Formula (1) includes at least K, and may further include at least one selected from the group consisting of Li, Na, Rb, Cs and NH₄⁺. A ratio of the number of moles of K to the total number of moles of A in the composition may be, for example, 0.90 or greater, preferably 0.95 or greater, or 0.97 or greater. The upper limit of the ratio of the number of moles of K may be, for example, 1 or less, or 0.995 or less.

In Formula (1), b is preferably in a range of 0.005 to 0.15, or may be in a range from 0.01 to 0.12, or from 0.015 to 0.1. Furthermore, c may be in a range of 1.8 to 2.2, and is preferably in a range from 1.9 to 2.1, or from 1.95 to 2.05. In addition, d is preferably in a range of 5.5 to 6.5, and may be in a range of 5.9 to 6.1, 5.95 to 6.05, or 5.97 to 6.03.

Furthermore, the fluoride particles may have a theoretical composition represented by Formula (1a) below.

A₂MF₆:Mn (1a)

In Formula (1a), A may include at least one selected from the group consisting of Li, Na, K, Rb, Cs, and NH₄⁺. M includes at least Si, and may further include at least one element selected from the group consisting of Group 4 elements, Group 13 elements, and Group 14 elements. Mn may be a tetravalent Mn ion.

A first composition, which is one aspect of the composition of the fluoride particles, may contain, as the element M, at least one element selected from the group consisting of Group 4 elements and Group 14 elements, preferably contains at least one element selected from the group consisting of Group 14 elements, more preferably contains Si and/or Ge, and even more preferably contains at least Si. In addition, in the first composition of the fluoride particles, the total number of moles of Si, Ge, and Mn per a total number of 2 moles of the alkali metal and the ammonium ion may be in a range from 0.9 to 1.1, preferably from 0.95 to 1.05, or from 0.97 to 1.03.

The first composition of the fluoride particles may be a composition represented by Formula (2) below.

A¹_{q}[M¹₁₋ₚMnₚFᵣ] (2)

In Formula (2), A¹ may include at least one selected from the group consisting of Li, Na, K, Rb, Cs, and NH₄⁺. M¹ includes at least one of Si and Ge, and may further include at least one element selected from the group consisting of Group 4 elements and Group 14 elements. Mn may be a tetravalent Mn ion. Moreover, p may satisfy 0<p<0.2, q is the absolute value of the charge of the [M¹₁₋ₚMnₚFᵣ] ion, and r may satisfy 5<r<7.

A¹ in Formula (2) includes at least K, and may further include at least one selected from the group consisting of Li, Na, Rb, Cs, and NH₄⁺. When A¹ includes an ammonium ion, the ratio of the number of moles of the ammonium ion to the total number of moles of A¹ in the composition may be, for example, 0.10 or less, and preferably may be 0.05 or less, or 0.03 or less. The lower limit of the ratio of the number of moles of the ammonium ion may be, for example, greater than 0, and may be preferably 0.005 or greater.

In Formula (2), p is preferably in a range of 0.005 to 0.15, 0.01 to 0.12, or 0.015 to 0.1. Furthermore, q may be, for example, in a range of 1.8 to 2.2, and is preferably in a range of 1.9 to 2.1, or 1.95 to 2.05. In addition, r is preferably in a range of 5.5 to 6.5, 5.9 to 6.1, 5.92 to 6.05, or 5.95 to 6.025.

The fluoride particles of the first composition may have a first theoretical composition represented by Formula (2a) below.

A¹₂M¹F₆:Mn (2a)

In Formula (2a), A¹ may include at least one selected from the group consisting of Li, Na, K, Rb, Cs, and NH₄⁺. M¹ includes at least one of Si and Ge, and may further include at least one element selected from the group consisting of Group 4 elements and Group 14 elements. Mn may be a tetravalent Mn ion.

A second composition, which is one aspect of the composition of the fluoride particles, may contain, as the element M, at least one element selected from the group consisting of Group 4 elements and Group 14 elements and at least one element of Group 13 elements, and preferably at least one element selected from the group consisting of Group 14 elements and at least one element of Group 13 elements, and more preferably at least Si and Al. In addition, in the second composition of the fluoride particles, the total number of moles of Si, Al, and Mn per a total number of 2 moles of the alkali metal and the ammonium ion may be in a range of 0.9 to 1.1, preferably 0.95 to 1.05, or 0.97 to 1.03. Furthermore, in the second composition of the fluoride particles, the number of moles of Al per a total number of 2 moles of the alkali metal and the ammonium ion may be in a range greater than 0 and 0.1 or less, and is preferably greater than 0 and 0.03 or less, in a range of 0.002 to 0.02, or in a range of 0.003 to 0.015.

The second composition of the fluoride particles may be a composition represented by Formula (3) below.

A²₁[M²₁₋ₛMnₛFᵤ] (3)

A² in Formula (3) includes at least K, and may further include at least one selected from the group consisting of Li, Na, Rb, Cs, and NH₄⁺. M² includes at least Si and Al, and may further include at least one element selected from the group consisting of Group 4 elements, Group 13 elements, and Group 14 elements. Mn may be a tetravalent Mn ion. Moreover, s may satisfy 0<s<0.2, t is the absolute value of the charge of the [M²₁₋ₛMnₛFᵤ] ion, and u may satisfy 5<u<7.

When A² in Formula (3) includes an ammonium ion, the ratio of the number of moles of the ammonium ion to the total number of moles of A² in the composition may be, for example, 0.10 or less, and is preferably 0.05 or less, or 0.03 or less. The lower limit of the ratio of the number of moles of the ammonium ion may be, for example, greater than 0, and may be preferably 0.005 or greater.

In Formula (3), s is preferably in a range from 0.005 to 0.15, from 0.01 to 0.12, or from 0.015 to 0.1. Furthermore, t may be in a range of 1.8 to 2.2, and is preferably in a range of 1.9 to 2.1, or 1.95 to 2.05. In addition, u is preferably in a range of 5.5 to 6.5, 5.9 to 6.1, 5.92 to 6.05, or 5.95 to 6.025.

Moreover, the fluoride particles of the second composition may have a second theoretical composition represented by Formula (3a) below.

A²₂Si₁₋ᵥAlᵥF₆₋ᵥ:Mn (3a)

A² in Formula (3a) includes at least K, and may further include at least one selected from the group consisting of Li, Na, Rb, Cs, and NH₄⁺. Furthermore, v may satisfy 0<v<1, and preferably satisfies 0.005<v<0.03. Mn may be a tetravalent Mn ion.

The fluoride phosphor may contain a fluorine compound containing zirconium and disposed on at least a portion of the surface of each fluoride particle. The fluorine compound may cover the surface of the fluoride particle in a film shape, or may be disposed on the surface of the fluoride particle in the form of a fluorine compound layer. The surface coverage ratio of the fluoride particle covered by the fluorine compound in the fluoride phosphor may be, for example, 50% or greater, and is preferably 80% or greater, or 90% or greater. The surface coverage ratio of the fluoride particle covered by the fluorine compound is calculated as a ratio of the area of the surface covered by the fluorine compound to the surface area of the fluoride particle.

The fluorine compound may be a compound containing zirconium and fluorine atoms in the composition, and may further contain, in the composition, at least one selected from the group consisting of an alkali metal and an ammonium ion. When the fluorine compound contains an alkali metal or an ammonium ion in the composition thereof, the fluorine compound preferably contains at least potassium as an alkali metal. When the fluorine compound contains potassium in the composition, the molar ratio of the potassium to the alkali metal and the ammonium ion may be, for example, 0.8 or greater, and is preferably 0.9 or greater, or 0.95 or greater. The fluorine compound may further contain, in the composition thereof, in addition to zirconium, a Group 4 atom other than zirconium, such as titanium. When the fluorine compound contains a Group 4 atom other than zirconium in the composition, the molar ratio of the Group 4 atom other than zirconium to zirconium may be, for example, 0.1 or less, preferably 0.01 or less, or 0.001 or less.

The fluorine compound may contain at least a compound having a composition represented by, for example, AZrF₅. Here, A may include at least one selected from the group consisting of Li, Na, K, Rb, Cs, and NH₄⁺. A includes at least K, and may further include at least one selected from the group consisting of Li, Na, Rb, Cs, and NH₄⁺, and may be substantially K. Here, the term “substantially” means that impurities that are inevitably mixed therein are allowed, and means that the content percentage of impurities is, for example, 5 mol % or less, 1 mol % or less, or 0.1 mol % or less. A ratio of the number of moles of K to the total number of moles of A in the composition may be, for example, 0.90 or greater, preferably 0.95 or greater, or 0.97 or greater. The upper limit of the ratio of the number of moles of K may be, for example, 1 or less, or 0.995 or less.

In terms of zirconium, the content of the fluorine compound in the fluoride phosphor may be, for example, in a range of 0.1 mass % to 10 mass %, and is preferably 0.3 mass % or greater, 0.5 mass % or greater, or 0.8 mass % or greater. Further, the content of the fluorine compound may be 5 mass % or less, or 2 mass % or less. The reliability of the light-emitting device tends to be further improved by setting the content of the fluorine compound in the above range. Moreover, such a content tends to suppress a decrease in powder luminance.

From the perspective of improving luminance, the volume-based median size of the fluoride phosphor may be, for example, in a range of 5 μm to 90 μm, and is preferably in a range of 10 μm to 70 μm, or 15 μm to 50 μm. From the perspective of improving luminance, the particle size distribution of the fluoride phosphor may have a single peak, and preferably has a single peak with a narrow distribution range. Specifically, in the volume-based particle size distribution, when the particle size corresponding to a 10% cumulative volume from the small size side is denoted by D₁₀, and the particle size corresponding to a 90% cumulative volume from the small size side is denoted by D₉₀, the ratio of D₉₀ to D₁₀ (D₉₀/D₁₀) may be, for example, 3.0 or less. Note that the volume-based median size is a particle size corresponding to a cumulative volume of 50% from the small size side in the volume-based particle size distribution, and the volume-based particle size distribution is measured using a laser diffraction particle size distribution measuring device.

The fluoride phosphor is, for example, a phosphor that is activated by tetravalent manganese, and the fluoride phosphor may absorb light of a short wavelength range of visible light and emit red light. Light with which the fluoride phosphor is irradiated may be primarily light in the blue range, and the peak wavelength of the light thereof may be, for example, in a wavelength range of 380 nm to 485 nm. The emission peak wavelength in the emission spectrum of the fluoride phosphor may be, for example, in a wavelength range from 610 nm to 650 nm. The full width at half maximum in the emission spectrum of the fluoride phosphor may be, for example, 10 nm or less.

### Method for Manufacturing Fluoride Phosphor

The method for manufacturing a fluoride phosphor includes a first step of providing fluoride particles having a specific composition, and a second step of bringing the provided fluoride particles into contact with a treatment solution containing complex ions containing zirconium and a fluoride ion, and thereby disposing a zirconium-containing fluorine compound on at least a portion of the surfaces of the fluoride particles. Here, the fluoride particles having a specific composition have a composition containing an element M including at least one element selected from the group consisting of Group 4 elements, Group 13 elements, and Group 14 elements; at least one selected from the group consisting of an alkali metal and an ammonium ion; manganese; and fluorine atoms, and when the total number of moles of the alkali metal and the ammonium ion is 2, the number of moles of the manganese is in a range greater than 0 and less than 0.2, the total number of moles of the element M is greater than 0.8 and less than 1, and the number of moles of fluorine atoms is greater than 5 and less than 7.

By causing the fluoride particles having the predetermined composition to come into contact with the treatment solution containing complex ions containing zirconium and a fluoride ion, a fluoride phosphor in which a zirconium-containing fluorine compound is disposed on at least a portion of the surfaces of the fluoride particles can be efficiently manufactured. In a light-emitting device provided with a wavelength conversion member containing the obtained fluoride phosphor and a resin, reliability in a high temperature environment, for example, is improved.

In the first step, fluoride particles having a predetermined composition are provided. In the provision step, provision may be achieved by acquiring the fluoride particles, or by manufacturing the desired fluoride particles. Note that the details of the provided fluoride particles are as described above.

For example, the fluoride particles can be manufactured as follows. In a case in which the fluoride particles have a first composition, for example, the fluoride particles having the first composition can be manufactured by a manufacturing method including a step of mixing a solution a and a solution b, the solution a containing at least hydrogen fluoride, a first complex ion including tetravalent manganese, and a second complex ion including a fluorine ion and at least one element selected from the group consisting of Group 4 elements and Group 14 elements, and the solution b containing at least hydrogen fluoride and an alkali metal including at least potassium.

The fluoride particle can also be manufactured by a manufacturing method including a step of mixing a first solution, a second solution, and a third solution, the first solution containing at least hydrogen fluoride and a first complex ion including tetravalent manganese, the second solution containing at least hydrogen fluoride and an alkali metal including at least potassium, and the third solution containing at least a second complex ion including a fluorine ion and at least one element selected from the group consisting of Group 4 elements and Group 14 elements. For the method for manufacturing the fluoride particles having the first composition, Japanese Patent Publication No. 2014-141684 A, Japanese Patent Publication No. 2015-143318 A, Japanese Patent Publication No. 2015-188075 A, and the like can be referenced, for example.

In a case in which the fluoride particles have a second composition, the fluoride particles having the second composition can be manufactured by, for example, a manufacturing method including providing fluoride particles having the first composition; providing fluoride particles containing Al, an alkali metal, and F; and carrying out a first heat treatment step of subjecting a mixture of the fluoride particles having the first composition and the fluoride particles containing Al, an alkali metal, and F to a first heat treatment in an inert gas atmosphere at a first heat treatment temperature in a range from 600° C. to 780° C. Here, the composition of the fluoride particles containing Al, an alkali metal, and F may be such that the ratio of the total number of moles of the alkali metal per mole of Al is in a range from 1 to 3, and the ratio of the number of moles of F per mole of Al is in a range from 4 to 6. Alternatively, the ratio of the total number of moles of the alkali metal per mole of Al may be in a range from 2 to 3, and the ratio of the number of moles of F per mole of Al may be in a range from 5 to 6. For the method for manufacturing the fluoride particles having the second composition, Japanese Patent Publication No. 2010-254933 A, Japanese Patent Publication No. 2022-099232 A, and the like can be referenced, for example.

In the second step, the provided fluoride particles are brought into contact with a treatment solution containing complex ions containing zirconium and a fluoride ion, whereby a zirconium-containing fluorine compound is disposed on at least a portion of the surfaces of the fluoride particles. When the fluoride particles are brought into contact with the treatment solution containing the complex ions containing zirconium and a fluoride ion, for example, a dissolution reaction occurs with some of the fluoride particles, and at least one kind of ion selected from the group consisting of an alkali metal ion and an ammonium ion constituting the fluoride particles, and complex ions containing the element M and fluoride ions are generated. It is considered that at least one kind of generated ion selected from the group consisting of the alkali metal ion and the ammonium ion reacts with the complex ion containing zirconium and a fluoride ion, whereby a zirconium-containing fluorine compound is disposed on the surfaces of the fluoride particles.

The treatment solution contains a liquid medium and the complex ions containing zirconium and fluoride ions. The liquid medium may contain at least water, and may be substantially water except for an organic solvent or the like described below.

Examples of the complex ions containing zirconium and fluoride ions include [ZrF₆]²⁻, [ZrF₇]³⁻, [ZrF₈]⁴⁻, [ZrF₅]⁻, [Zr₂F₁₀]²⁻, [Zr₂F₁₂]⁴⁻, [Zr₂F₁₃]⁵⁻, [Zr₂F₁₄]⁶⁻, and [Zr₆F₃₁]⁷⁻. The treatment solution preferably contains at least a complex ion having a composition represented by [ZrF₆]²⁻. Examples of a counter cation of the complex ion containing zirconium and a fluoride ion include a hydrogen ion and an ammonium ion, and at least a hydrogen ion is preferably included. In terms of zirconium content, the content percentage of the complex ions containing zirconium and fluoride ions in the treatment solution may be, for example, 0.01 mol/L or greater, and preferably 0.02 mol/L or greater. Moreover, the content percentage of the complex ions may be, for example, 1 mol/L or less, and is preferably 0.5 mol/L or less.

The treatment solution may further contain an oxoacid of boron in addition to the complex ions containing zirconium and fluoride ions. Examples of the oxoacid of boron include orthoboric acid (H₃BO₃), metaboric acid ((HBO₂)ₙ), perboric acid (HBO₃), hypoboric acid (H₄B₂O₄), boronic acid (H₃BO₂), and borinic acid (H₃BO). The oxoacid of boron contained in the treatment solution may contain at least orthoboric acid. When the treatment solution contains an oxoacid of boron, for example, hydrogen fluoride generated in association with the generation of a fluorine compound containing zirconium can be removed as fluoroboric acid (for example, HBF₄), and generation of the fluorine compound containing zirconium can be promoted. Specifically, when the treatment solution contains orthoboric acid, for example, a reaction like that described below is considered to occur. Note that in the following formula, A includes at least one selected from the group consisting of an alkali metal and an ammonium ion.

2H₂ZrF₆+A₂SiF₆→2AZrF₅+H₂SiF₆+2HF

H₃BO₃+4HF→HBF₄+3H₂O

When the treatment solution contains an oxoacid of boron, the content percentage of the oxoacid of boron in terms of boron content in the treatment solution may be, for example, 0.01 mol/L or more, and is preferably 0.02 mol/L or 0.04 mol/L or more. Moreover, the content percentage of the oxoacid of boron may be, for example, 0.4 mol/L or less, and preferably 0.2 mol/L or less.

The treatment solution may further contain a reducing agent. When a reducing agent is contained, for example, tetravalent manganese ions, which may be eluted from the fluoride particles, are reduced, and thus coloring caused by tetravalent manganese ions can be suppressed. Examples of the reducing agent include hydrogen peroxide and oxalic acid. The reducing agent preferably contains at least hydrogen peroxide. Hydrogen peroxide has little impact on the fluoride particles and can efficiently reduce tetravalent manganese ions. Further, hydrogen peroxide is ultimately decomposed into harmless water and oxygen, and therefore hydrogen peroxide can be easily used in manufacturing processes and can reduce the environmental load.

When the treatment solution contains a reducing agent, the content percentage of the reducing agent in the treatment solution may be, for example, in a range from 0.1 mass % to 20 mass %, and is preferably 0.5 mass % or greater or 5 mass % or less. The content percentage of the reducing agent may be, for example, in a range from 0.02 mol/L to 4 mol/L, is preferably 0.05 mol/L or greater, or 0.1 mol/L or greater, and is preferably 2 mol/L or less, or 1 mol/L or less.

In the second step, the treatment solution that is brought into contact with the fluoride particles may further contain an organic solvent. When the treatment solution contains an organic solvent, for example, the solubility of the zirconium-containing fluorine compound in the treatment solution decreases, and the fluorine compound can be more efficiently disposed on the surfaces of the fluoride particles. In addition, the organic solvent can promote the generation of the zirconium-containing fluorine compound. The organic solvent need only be miscible with water, and examples of the organic solvent include alcohol-based solvents of three or fewer carbons, such as methanol, ethanol, propyl alcohol, and isopropyl alcohol, ketone-based solvents such as acetone and methyl ethyl ketone, and nitrile-based solvents such as acetonitrile. The organic solvent contained in the solution preferably contains at least an alcohol of 3 or fewer carbons.

When the treatment solution contains an organic solvent in the second step, the content percentage of the organic solvent in the treatment solution containing the organic solvent may be, for example, 5 vol % or more, and is preferably 10 vol % or more, or 15 vol % or more. Moreover, the content percentage of the organic solvent may be, for example, 80 vol % or less, and is preferably 70 vol % or less, 60 vol % or less, or 55 vol % or less. Here, the volume of the treatment solution containing an organic solvent is the sum of the volume of the treatment solution not containing the organic solvent and the volume of the organic solvent added to the treatment solution, and a change in volume due to mixing of water and the organic solvent is ignored.

As a mass ratio in relation to the fluoride particles, the amount of the treatment solution used for contact with the fluoride particles in the second step may be, for example, in a range from 100 mass % to 3000 mass %, and is preferably 300 mass % or more, or 500 mass % or more, and is preferably 2500 mass % or less, or 2000 mass % or less. Furthermore, when the mass ratio of the treatment solution is in the above range, the zirconium-containing fluorine compound tends to be more uniformly disposed on the surfaces of the fluoride particles.

Contact between the fluoride particles and the treatment solution can be caused by, for example, mixing the fluoride particles and the treatment solution. The contact may also be achieved while stirring the treatment solution containing the fluoride particles. The contact temperature of the fluoride particles and the treatment solution may be, for example, in a range from 10° C. to 50° C., and is preferably 20° C. or higher, or 35° C. or lower. Moreover, a contact period may be, for example, in a range from 1 hour to 40 hours, and is preferably 2 hours or more, or 30 hours or less. The atmosphere for contact may be an air atmosphere or an inert gas atmosphere.

The method for manufacturing a fluoride phosphor may further include, after the second step, additional steps such as a step of recovering, through solid-liquid separation, the fluoride phosphor obtained in the second step, and a step of drying the solid-liquid separated fluoride phosphor.

### Light-Emitting Device

The light-emitting device includes a wavelength conversion member containing a resin and the fluoride phosphor; and a light source having an emission peak wavelength in a wavelength range from 380 nm to 485 nm. The light-emitting device may further include other constituent members as necessary.

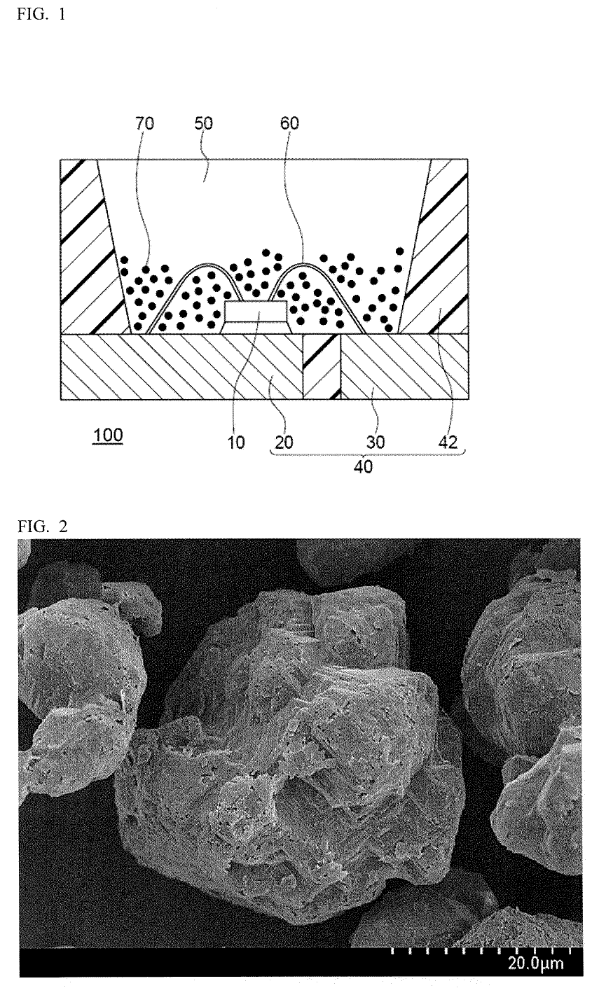

An example of the light-emitting device will be described on the basis of the drawings. FIG. 1 is a schematic cross-sectional view illustrating one example of a light-emitting device according to the present embodiment. This light-emitting device is an example of a surface-mounted light-emitting device. The light-emitting device 100 includes a light-emitting element 10, which is a light source that emits light having an emission peak wavelength on the short-wavelength side of visible light (for example, in a range of 380 nm to 485 nm), and a formed body 40 on which the light-emitting element 10 is mounted. The formed body 40 includes a first lead 20 and a second lead 30, and is integrally formed using a thermoplastic resin or a thermosetting resin. A recessed portion having lateral surfaces and a bottom surface defined by a substrate is formed in the formed body 40, and the light-emitting element 10 is placed on the bottom surface of the recessed portion. The light-emitting element 10 includes a pair of positive and negative electrodes, and the pair of the positive and negative electrodes are electrically connected to the first lead 20 and the second lead 30 via wires 60. The light-emitting element 10 is covered with a wavelength conversion member 50. The wavelength conversion member 50 contains a phosphor 70 including a fluoride phosphor that converts the wavelength of light from the light-emitting element 10. The phosphor 70 may contain the fluoride phosphor, and a light-emitting material which, in response to excitation light from the light-emitting element 10, emits light having an emission peak wavelength in a wavelength range different from that of the fluoride phosphor.

The wavelength conversion member may contain a resin and a phosphor. Examples of the resin constituting the wavelength conversion member include a silicone resin, an epoxy resin, a modified silicone resin, a modified epoxy resin, and an acrylic resin. For example, the refractive index of a silicone resin may be in a range from 1.35 to 1.55, more preferably in a range from 1.38 to 1.43. When the refractive index of the silicone resin is in these ranges, the silicone resin has good transmissivity and can be suitably used as a resin constituting the wavelength conversion member. The refractive index of the silicone resin is the refractive index after curing, and is measured in accordance with JIS K 7142:2008. The wavelength conversion member may further include a light-diffusing material in addition to the resin and the phosphor. When a light-diffusing material is included, directivity from the light-emitting element can be alleviated, and a viewing angle can be increased. Examples of the light-diffusing material include silicon oxide, titanium oxide, zinc oxide, zirconium oxide, and aluminum oxide.

The light-emitting element emits light having an emission peak wavelength in a wavelength range of 380 nm to 485 nm, which is a short wavelength range of visible light. The light-emitting element may be a light source that excites the fluoride phosphor. The light-emitting element preferably has an emission peak wavelength in a range of 380 nm to 480 nm, more preferably has an emission peak wavelength in a range from 410 nm to 480 nm, and even more preferably has an emission peak wavelength in a range from 430 nm to 480 nm. A semiconductor light-emitting element is preferably used as the light-emitting element of the light source. A stable light-emitting device that exhibits high efficiency and high output linearity with respect to an input and that is strong against mechanical impact can be obtained by using a semiconductor light-emitting element as the light source. As the semiconductor light-emitting element, for example, a semiconductor light-emitting element that uses a nitride-based semiconductor can be used. The full width at half maximum of the emission peak in the emission spectrum of the light-emitting element is preferably 30 nm or less, for example.

The light-emitting device includes a fluoride phosphor. Details of the fluoride phosphor included in the light-emitting device are described above. The fluoride phosphor is contained, for example, in the wavelength conversion member covering the light source. In the light-emitting device in which the light source is covered with the wavelength conversion member containing the fluoride phosphor, part of the light emitted from the light source is absorbed by the fluoride phosphor and emitted as red light. When a light source that emits light having an emission peak wavelength in the range of 380 nm to 485 nm is used, the emitted light can be utilized more efficiently, loss of light emitted from the light-emitting device can be reduced, and a highly efficient light-emitting device can be provided.

The light-emitting device preferably further includes, in addition to the fluoride phosphor, a light-emitting material other than the fluoride phosphor. The light-emitting material other than the fluoride phosphor may be any material that absorbs light from the light source and converts the light into light having a wavelength different from that of the fluoride phosphor. Like the fluoride phosphor, for example, the light-emitting material can be contained in the wavelength conversion member.

The light-emitting material may have an emission peak wavelength in a range from 495 nm to 573 nm, and may preferably be at least one material selected from the group consisting of a β-sialon phosphor, a halosilicate phosphor, a silicate phosphor, a rare earth-aluminate phosphor, a perovskite light-emitting material, and a nitride phosphor. The β-sialon phosphor may have a composition represented by Formula (IIa), for example. The halosilicate phosphor may have a composition represented by Formula (IIb), for example. The silicate phosphor may have a composition represented by Formula (IIc), for example. The rare earth-aluminate phosphor may have a composition represented by Formula (IId). The perovskite light-emitting material may have a composition represented by Formula (IIe), for example. The nitride phosphor may have a composition represented by Formula (IIf), (IIg), or (IIh), for example. When the wavelength conversion member contains a β-sialon phosphor or a perovskite light-emitting material as the light-emitting material other than the fluoride phosphor, a light-emitting device that is used as, for example, a light source for a backlight can have a wider range of color reproducibility. When the wavelength conversion member contains, as the light-emitting material other than the fluoride phosphor, a halosilicate phosphor, a silicate phosphor, a rare earth-aluminate phosphor, or a nitride phosphor, a light-emitting device that is used as, for example, an illumination light source can have higher color rendering properties or higher luminous efficiency.

Si₆₋ₓAlₓOₓN₈₋ₓ:Eu (IIa)

(In Formula (IIa), x is a number satisfying 0<x≤4.2.)

(Ca,Sr,Ba)₈MgSi₄O₁₆(F,Cl,Br)₂:Eu (IIb)

(Ba,Sr,Ca,Mg)₂SiO₄:Eu (IIc)

(Y,Lu,Gd,Tb)₃(Al,Ga)₅O₁₂:Ce (IId)

CsPb(F,Cl,Br,I)₃ (IIe)

(La,Y,Gd)₃Si₆N₁₁:Ce (IIf)

(Sr,Ca)LiAl₃N₄:Eu (IIg)

(Ca,Sr)AlSiN₃:Eu (IIh)

The wavelength conversion member may further contain at least one type of quantum dot in addition to the fluoride phosphor. The quantum dots may be quantum dots that absorb light from the light source and convert the light to light of a wavelength differing from that of the fluoride phosphor, or may be quantum dots that convert the absorbed light to light of approximately the same wavelength. Examples of quantum dots include quantum dots having a perovskite structure with a composition such as (Cs, FA, MA)(Pb, Sn)(Cl, Br, I)₃ (where FA denotes formamidinium and MA denotes methylammonium), quantum dots having a chalcopyrite structure with a composition such as (Ag, Cu, Au)(In, Ga)(S, Se, Te)₂, semiconductor quantum dots such as (Cd, Zn)(Se, S), and InP-based semiconductor quantum dots. The quantum dots may include at least one type selected from the group consisting of these. Here, a plurality of elements or cations separated by commas (,) in a formula representing the composition of the quantum dots means that at least one element among the plurality of elements or cations is contained in the composition.

### EXAMPLES

The present disclosure is specifically described below through examples; however, the present disclosure is not limited to these examples.

### Manufacturing Example 1

Through a known method, fluoride particles were obtained as a phosphor having a theoretical composition represented by K₂[Si_{0.960}Mn_{0.040}F₆] with a Mn content percentage of 1.00 mass %.

### Example 1

The fluoride particles provided in Manufacturing Example 1 were weighed to obtain an amount of 20 g, which was then put into a treatment solution provided by mixing 60 g of a hexafluorozirconic acid (H₂ZrF₆) aqueous solution adjusted to 1.0 mol/L, 15 g of an orthoboric acid (H₃BO₃) aqueous solution adjusted to 1.0 mol/L, 30 g of a hydrogen peroxide (H₂O₂) aqueous solution adjusted to 1.47 mol/L, 45 g of pure water, and 38 mL (30 g) of ethanol in a 250 mL cylindrical plastic bottle, after which the contents were stirred at room temperature for 5 hours using a mixer (product name: Mix Rotor MR-5, available from AS ONE Corporation). The resultant precipitate was subjected to solid-liquid separation, and then washed with ethanol and dried at 90° C. for 10 hours, whereby a fluoride phosphor of Example 1 was produced.

### Example 2

A fluoride phosphor of Example 2 was produced by substantially the same method as that in Example 1 with the exception that the addition amount of the fluoride particles was 40 g.

### Example 3

A fluoride phosphor of Example 3 was produced by substantially the same method as that in Example 1 with the exception that the stirring time was changed to 20 hours.

### Example 4

A fluoride phosphor of Example 4 was produced by substantially the same method as that in Example 1 with the exception that the amount of a H₂ZrF₆ aqueous solution was changed to 15 g, the amount of pure water was changed to 90 g, and the addition amount of ethanol was changed to 152 mL (120 g).

### Comparative Example 1

The fluoride particles obtained in Manufacturing Example 1 were used as the fluoride phosphor of Comparative Example 1.

### Evaluation

The relative luminance, manganese content, and zirconium content of the fluoride phosphors of Examples 1 to 4 and Comparative Example 1 obtained as described above were evaluated as follows.

### Relative Luminance

Using the data of the measured emission spectrum of each fluoride phosphor, the emission luminance values of the fluoride phosphors of Examples 1 to 4 were determined as relative luminance values based on the emission luminance of the fluoride phosphor of Comparative Example 1 being 100%. The results are shown in Table 1 below.

### Manganese Content

The manganese content percentage of each of the fluoride phosphors was analyzed by inductively coupled plasma atomic emission spectroscopy (ICP-AES) to determine the content percentage (Mn content: mass %) with respect to the fluoride phosphor. The results are shown in Table 1 below.

### Zirconium Content

The zirconium content percentage of each of the fluoride phosphors was analyzed by inductively coupled plasma atomic emission spectroscopy (ICP-AES) to determine the content percentage (Zr content: mass %) with respect to the fluoride phosphor. The results are shown in Table 1 below.

TABLE 1

| | | Treatment Solution | | | | | | | | |
|---|---|---|---|---|---|---|---|---|---|---|
| | Fluoride | Liquid | | | | | Contact | Relative | Mn | Zr |
| | Particles | Amount | H₂O₂ | H₂ZrF₆ | H₃BO₃ | Ethanol | Time | Luminance | Content | Content |
| | (g) | (mL) | (mol/L) | (mol/L) | (mol/L) | (vol %) | (h) | (%) | (mass %) | (mass %) |
| Example 1 | 20 | 188 | 0.23 | 0.32 | 0.08 | 20 | 5 | 100.2 | 0.98 | 1.0 |
| Example 2 | 40 | 188 | 0.23 | 0.32 | 0.08 | 20 | 5 | 100.7 | 0.98 | 0.6 |
| Example 3 | 20 | 188 | 0.23 | 0.32 | 0.08 | 20 | 20 | 87.3 | 0.90 | 4.8 |
| Example 4 | 20 | 302 | 0.15 | 0.05 | 0.05 | 50 | 5 | 96.9 | 0.98 | 1.4 |
| Comparative | — | | | | | | — | 100.0 | 1.00 | <0.001 |
| Example 1 | | | | | | | | | | |

In the fluoride phosphor of Comparative Example 1, the detected amount of Zr was equal to or less than the measurement limit. In contrast, Zr was detected in the fluoride phosphors of Examples 1 to 4.

### Scanning Electron Microscope Observation

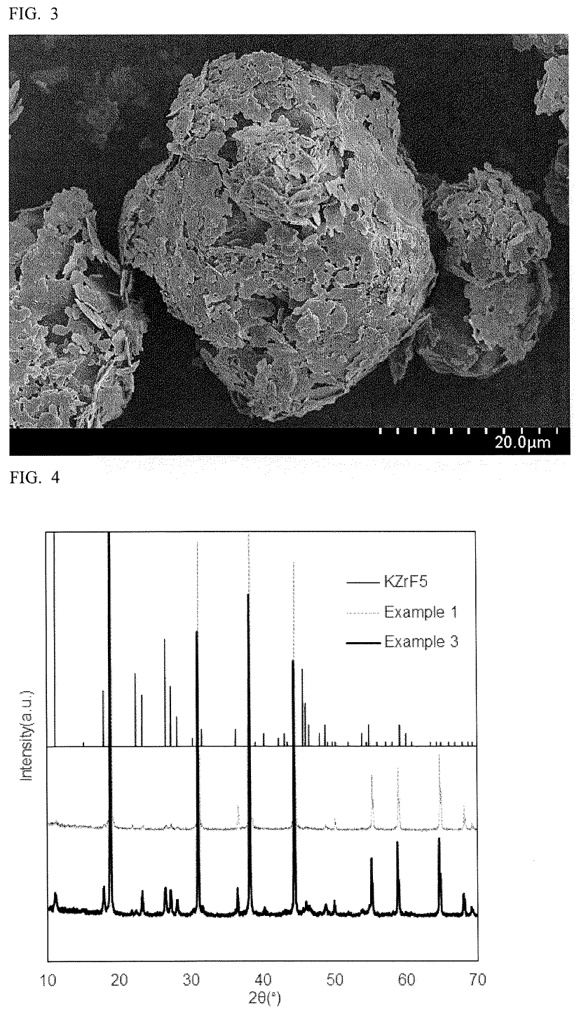

Scanning electron microscope (SEM) images of the fluoride phosphors obtained in Examples 1 and 3 were obtained using a SEM. The SEM image of the fluoride phosphor of Example 1 is shown in FIG. 2, and the SEM image of the fluoride phosphor of Example 3 is shown in FIG. 3.

### X-Ray Diffraction Spectra

The X-ray diffraction (XRD) spectra of the fluoride phosphors of Examples 1 and 3 were measured using a sample horizontal multi-purpose X-ray diffractometer (product name: Ultima IV, available from Rigaku Corporation) and an X-ray source of CuKα rays (2=0.15418 nm, a tube voltage of 40 kV, a tube current of 40 mA) under measurement conditions including an angle in a range from 10° to 70°, a scanning width of 0.02°, and a scanning speed of 20°/min. The results are shown in FIG. 4 together with the XRD spectrum of KZrF₅.

### Light-Emitting Device Manufacturing Example

A light-emitting device 100 like that illustrated in FIG. 1 was manufactured as follows. The fluoride phosphor of Example 1, Example 2, or Comparative Example 1 and a β-sialon phosphor having a composition represented by Si_{5.81}Al_{0.19}O_{0.19}N_{7.81}: Eu and having an emission peak wavelength near 540 nm were used as the phosphor 70. A resin composition was obtained by mixing a silicone resin with the fluoride phosphor and the β-sialon phosphor such that as the chromaticity coordinates in the CIE1931 color system, x was around 0.280 and y was around 0.270. Subsequently, a formed body 40 having a recessed portion was provided, a light-emitting element 10 formed of a gallium nitride-based compound semiconductor and having an emission peak wavelength of 451 nm was disposed on the first lead 20 at the bottom of the recessed portion, and then electrodes of the light-emitting element 10 were connected to the first lead 20 and the second lead 30 by respective wires 60. Further, using a syringe, the resin composition was injected into the recessed portion of the formed body 40 so as to cover the light-emitting element 10, after which the resin composition was cured to form a wavelength conversion member 50, whereby respective light-emitting devices 100 were manufactured.

### Durability Test 1

Each light-emitting device manufactured using the fluoride phosphor obtained in Example 1, Example 2, or Comparative Example 1 was subjected to a durability test 1 by being stored in an environmental tester at a temperature of 85° C. and a relative humidity of 85% for 500 hours. A lumen maintenance rate (%) of each light-emitting device after the durability test 1 was determined based on the luminous flux of the light-emitting device before the storage in the environmental tester being 100%. A higher lumen maintenance rate (%) indicates better durability against high temperature and high humidity conditions. The results are shown in Table 2.

### Durability Test 2

Each light-emitting device manufactured using the fluoride phosphor obtained in Example 1, Example 2, or Comparative Example 1 was subjected to a durability test 2 in which the light-emitting device was caused to continuously emit light at a current value of 150 mA in a non-humidified environmental tester at a temperature of 85° C. and then evaluated after 500 hours. The x value of chromaticity in the CIE1931 color system of the light-emitting device before the durability test 2 was set as an initial value, and an absolute value of a value changed from the initial x value in the CIE1931 color system of the light-emitting device after the durability test 2 was determined as Δx. With Δx of the light-emitting device manufactured using the fluoride phosphor of Comparative Example 1 being set as a reference (100%), a Δx change rate (%) relative to the reference of 100% was determined for the Δx obtained for each of the light-emitting devices of the Examples. A lower relative Δx change rate (%) indicates a smaller change in chromaticity and higher durability. The results are shown in Table 2.

TABLE 2

| | | Durability Test 1 | Durability Test 2 |
|---|---|---|---|
| | | Lumen | Δx |
| | Zr Content | Maintenance | Change |
| | (mass %) | Rate (%) | Rate (%) |
| Example 1 | 1.0 | 91.5 | 78.7 |
| Example 2 | 0.6 | 91.0 | 83.9 |
| Comparative | <0.001 | 87.4 | 100.0 |
| Example 1 | | | |

In comparison with the light-emitting device obtained using the fluoride phosphor of Comparative Example 1, the light-emitting devices obtained using the fluoride phosphors of Examples 1 and 2 exhibited higher lumen maintenance rates in the durability test 1 and lower Δx change rates in the durability test 2 and therefore were better in durability. Also, in a comparison of the light-emitting device obtained using the fluoride phosphor of Example 1 with the light-emitting device obtained using the fluoride phosphor of Example 2, the light-emitting device obtained using the fluoride phosphor of Example 1 having a higher Zr content exhibited a higher lumen maintenance rate in the durability test 1 and a lower Δx change rate in the durability test 2 than the light-emitting device obtained using the fluoride phosphor of Example 2. From this, it is clear that a light-emitting device that uses a fluoride phosphor coated with a larger amount of a fluorine compound containing at least zirconium and fluorine exhibits higher durability.

It is to be understood that although the present invention has been described with regard to preferred embodiments thereof, various other embodiments and variants may occur to those skilled in the art, which are within the scope and spirit of the invention, and such other embodiments and variants are intended to be covered by the following claims.

Although the present disclosure has been described with reference to several exemplary embodiments, it is to be understood that the words that have been used are words of description and illustration, rather than words of limitation. Changes may be made within the purview of the appended claims, as presently stated and as amended, without departing from the scope and spirit of the disclosure in its aspects. Although the disclosure has been described with reference to particular examples, means, and embodiments, the disclosure may be not intended to be limited to the particulars disclosed; rather the disclosure extends to all functionally equivalent structures, methods, and uses such as are within the scope of the appended claims.

One or more examples or embodiments of the disclosure may be referred to herein, individually and/or collectively, by the term “disclosure” merely for convenience and without intending to voluntarily limit the scope of this application to any particular disclosure or inventive concept. Moreover, although specific examples and embodiments have been illustrated and described herein, it should be appreciated that any subsequent arrangement designed to achieve the same or similar purpose may be substituted for the specific examples or embodiments shown. This disclosure may be intended to cover any and all subsequent adaptations or variations of various examples and embodiments. Combinations of the above examples and embodiments, and other examples and embodiments not specifically described herein, will be apparent to those of skill in the art upon reviewing the description.

In addition, in the foregoing Detailed Description, various features may be grouped together or described in a single embodiment for the purpose of streamlining the disclosure. This disclosure may be not to be interpreted as reflecting an intention that the claimed embodiments require more features than are expressly recited in each claim. Rather, as the following claims reflect, inventive subject matter may be directed to less than all of the features of any of the disclosed embodiments. Thus, the following claims are incorporated into the Detailed Description, with each claim standing on its own as defining separately claimed subject matter.

The above disclosed subject matter shall be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure may be determined by the broadest permissible interpretation of the following claims and their equivalents, and shall not be restricted or limited by the foregoing detailed description.

All publications, patent applications, and technical standards mentioned in this specification are herein incorporated by reference to the same extent as if each individual publication, patent application, or technical standard was specifically and individually indicated to be incorporated by reference.

What is claimed is:

1. A fluoride phosphor comprising:
a fluoride particle; and
a fluorine compound containing zirconium and disposed on at least a portion of a surface of the fluoride particle, wherein
the fluoride particle has a composition comprising:
an element M comprising at least one element selected from the group consisting of Group 4 elements, Group 13 elements, and Group 14 elements,
at least one selected from the group consisting of an alkali metal and an ammonium ion,
manganese, and
fluorine atoms,
wherein, when a total number of moles of the alkali metal and the ammonium ion is 2, a number of moles of the manganese is greater than 0 and less than 0.2, a total number of moles of the element M is greater than 0.8 and less than 1, and a number of moles of the fluorine atoms is greater than 5 and less than 7.

2. The fluoride phosphor according to claim 1, wherein the fluoride particle has a composition represented by Formula (1):
A_{c}[M_{1-b}Mn_{b}F_{d}] (1)
wherein in Formula (1), A comprises at least one selected from the group consisting of Li, Na, K, Rb, Cs, and NH₄⁺; M comprises at least one element selected from the group consisting of Group 4 elements, Group 13 elements, and Group 14 elements, and comprises at least Si; and b satisfies 0<b<0.2, c is an absolute value of a charge of the [M_{1-b}Mn_{b}F_{d}] ion, and d satisfies 5<d<7.

3. The fluoride phosphor according to claim 1, wherein a content of the fluorine compound is in a range of 0.1 mass % to 10 mass % in terms of zirconium.

4. The fluoride phosphor according to claim 1, wherein the fluorine compound comprises at least a compound having a composition represented by KZrF₅.

5. The fluoride phosphor according to claim 1, wherein the fluoride particle has a composition in which the alkali metal contains potassium, a ratio of a number of moles of the potassium to the total number of moles of the alkali metal and the ammonium ion is in a range of 0.9 to 1, the element M contains silicon, and a ratio of a number of moles of silicon to the total number of moles of the element M is in a range of 0.9 to 1.

6. A method for manufacturing a fluoride phosphor, the method comprising:
providing a fluoride particle having a composition comprising an element M comprising at least one selected from the group consisting of Group 4 elements, Group 13 elements, and Group 14 elements; at least one selected from the group consisting of an alkali metal and an ammonium ion; manganese; and fluorine atoms, wherein, when a total number of moles of the alkali metal and the ammonium ion is 2, a number of moles of the manganese is greater than 0 and less than 0.2, a total number of moles of the element M is greater than 0.8 and less than 1, and a number of moles of the fluorine atoms is greater than 5 and less than 7; and
bringing the fluoride particle into contact with a treatment solution containing a complex ion containing zirconium and a fluoride ion, and thereby disposing a zirconium-containing fluorine compound on at least a portion of a surface of the fluoride particle.

7. The method according to claim 6, wherein the fluoride particle has a composition represented by Formula (1):
A_{c}[M_{1-b}Mn_{b}F_{d}] (1)
wherein in Formula (1), A comprises at least one selected from the group consisting of Li, Na, K, Rb, Cs, and NH₄₊; M comprises at least one element selected from the group consisting of Group 4 elements, Group 13 elements, and Group 14 elements, and comprises at least Si; and b satisfies 0<b<0.2, c is an absolute value of a charge of the [M_{1-b}Mn_{b}F_{d}] ion, and d satisfies 5<d<7.

8. The method according to claim 6, wherein the treatment solution further contains orthoboric acid.

9. The method according to claim 8, wherein a concentration of the orthoboric acid in the treatment solution is 0.04 mol/L or greater.

10. The method according to claim 6, wherein the treatment solution further contains an organic solvent.

11. The method according to claim 10, wherein a content of the organic solvent is 15 vol % or more.

12. The method according to claim 10, wherein the organic solvent contains an alcohol having 3 or fewer carbons.

13. The method according to claim 6, wherein the treatment solution further contains a reducing agent.

14. A light-emitting device comprising:
the fluoride phosphor according to claim 1; and
a light source having an emission peak wavelength in a range of 380 nm to 485 nm.

15. The light-emitting device according to claim 14, further comprising a light-emitting material having an emission peak wavelength in a range of 495 nm to 573 nm.

16. A light-emitting device comprising:
the fluoride phosphor according to claim 2; and
a light source having an emission peak wavelength in a range of 380 nm to 485 nm.

17. The light-emitting device according to claim 16, further comprising a light-emitting material having an emission peak wavelength in a range of 495 nm to 573 nm.

18. A light-emitting device comprising:
the fluoride phosphor according to claim 3; and
a light source having an emission peak wavelength in a range of 380 nm to 485 nm.

19. The light-emitting device according to claim 18, further comprising a light-emitting material having an emission peak wavelength in a range of 495 nm to 573 nm.
